(19) United States
(12) Patent Application Publication
(10) Pub. No.: US 2026/0218045 A1
(43) Pub. Date: Jul. 30, 2026

(54) QUANTUM DOT, LIGHT-EMITTING MODULE AND METHOD FOR SYNTHESIZING QUANTUM DOT

(71) Applicants: Guangdong Juhua Research Institute of Advanced Display, Guangzhou, Guangdong (CN); TCL Technology Group Corporation, Huizhou, Guangdong (CN)

(72) Inventor: Jiawei QIANG, Guangzhou, Guangdong (CN)

(73) Assignees: Guangdong Juhua Research Institute of Advanced Display, Guangzhou, Guangdong (CN); TCL Technology Group Corporation, Huizhou, Guangdong (CN)

(21) Appl. No.: 19/144,490

(22) PCT Filed: Sep. 26, 2023
(86) PCT No.: PCT/CN2023/121473

§ 371 Date: Jun. 29, 2025

(30) Foreign Application Priority Data
Dec. 30, 2022 (CN) 202211740605.5

(51) Int. Cl. C09K 11/88; B82Y 20/00; B82Y 40/00; C09K 113/00; H10K 50/115; H10K 50/15; H10K 50/16; H10K 50/17

(52) U.S. Cl. CPC C09K 11/883; H10K 50/115; B82Y 20/00; B82Y 40/00; C09K 2113/00; H10K 50/15; H10K 50/16; H10K 50/17

(57) ABSTRACT

A quantum dot, a light-emitting module and a synthesis method of the quantum dot are provided. The quantum dot includes a seed crystal and a quantum dot material layer grown on the surface of the seed crystal. In the quantum dot, the quantum dot material layer is grown on the surface of the seed crystal, the quantum dot material is attached to the seed crystal for oriented growth, thereby achieving low lattice stress during quantum dot growth, and allowing the quantum dot to have few growth defects and high performance.

This disclosure claims priority of the Chinese patent application with the Chinese Patent Application No. 202211740605.5, filed in the China National Intellectual Property Administration on Dec. 30, 2022, and entitled “QUANTUM DOT, LIGHT-EMITTING MODULE AND METHOD FOR SYNTHESIZING QUANTUM DOT”, which is incorporated herein by reference in its entirety.

### TECHNICAL FIELD

The present disclosure relates to a field of quantum dots, and in particular to a quantum dot, a light-emitting module and a method for synthesizing quantum dot.

### BACKGROUND

Quantum dot, as a three-dimensional confined zero-dimensional nanomaterial, has a very high application in the display field. The thermodynamic stability of spherical quantum dot is higher than that of other morphologies, and the spherical quantum dot has better luminous efficiency. Quantum dot luminescence mainly depends on the core luminescence. Researchers have proposed that the defects on the surface of the core of the quantum dot may be passivated by coating shell, but the defects generated inside the core during the growth of the core may not be solved, thereby causing the electrons and holes to be captured by the defects during the luminescence of the quantum dot, so that non-radiative luminescence is formed, and the luminous efficiency of the quantum dot is reduced.

At present, the growth of the core of the quantum dot is mainly through high-temperature growth to reduce the defects in the core growth process, and through high-temperature injection to form a better crystalline seed in the initial stage of the core growth, and to mature in a high-temperature state to provide higher energy for the growth of the core, thereby improving the quality of the core.

However, there is still a problem of lattice growth stress in the growth of core, the lattice growth stress may cause lattice growth mismatch, causing exciton quenching, thereby reducing the luminous efficiency. Moreover, the same growth defects also exist in the quantum dot with a single structure.

### Technical Solution

In view of this, the present disclosure provides a quantum dot, a light-emitting module and a method for synthesizing quantum dot.

The present disclosure provides a quantum dot including a seed crystal and a quantum dot material layer grown on the surface of the seed crystal.

Optionally, in some embodiments, the quantum dot further includes a shell coated outside the quantum dot material layer.

Optionally, in some embodiments, the seed crystal is a semiconductor seed crystal or a single-crystal seed crystal; or
the seed crystal is a ZSM-5 molecular sieve, a Silicalite-1 all-silica molecular sieve, or a nano single-crystal silicon; or
the seed crystal is an intrinsic semiconductor, a P-type doped semiconductor, or an N-type doped semiconductor.

Optionally, in some embodiments, an average particle size of the seed crystal ranges from 1 nm to 2 nm, and an average thickness of the quantum dot material layer ranges from 3 nm to 4 nm; and/or

in the quantum dot, a molar percentage of the seed crystal ranges from 2% to 10%, and a molar percentage of the quantum dot material layer ranges from 90% to 98%.

Optionally, in some embodiments, an average particle size of the seed crystal ranges from 1 nm to 2 nm, an average thickness of the quantum dot material layer ranges from 3 nm to 4 nm, and a total thickness of the shell ranges from 2 nm to 3 nm; and/or

in the quantum dot, a molar percentage of the seed crystal ranges from 2% to 10%, a molar percentage of the quantum dot material layer ranges from 50% to 70%, and a molar percentage of the shell ranges from 20% to 40%.

Optionally, in some embodiments, a material of the quantum dot material layer and a material of the shell layer are independently selected from one or more of a group II-VI compound, a group IV-VI compound, a group III-V compound, and a group I-III-VI compound; the group II-VI compound is selected from one or more of CdS, CdSe, CdTe, ZnS, ZnSe, ZnTe, ZnO, HgS, HgSe, HgTe, CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, CdZnSeS, CdZnSeTe, CdZnSTe, CdHgSeS, CdHgSeTe, CdHgSTe, HgZnSeS, HgZnSeTe, and HgZnSTe; the group IV-VI compound is selected from one or more of SnS, SnSe, SnTe, PbS, PbSe, PbTe, SnSeS, SnSeTe, SnSTe, PbSeS, PbSeTe, PbSTe, SnPbS, SnPbSe, SnPbTe, SnPbSSe, SnPbSeTe, SnPbSTe; the group III-V compound is selected from one or more of GaN, GaP, GaAs, GaSb, AlN, AIP, AlAs, AlSb, InN, InP, InAs, InSb, GaNP, GaNAs, GaNSb, GaPAs, GaPSb, AlNP, AlNAs, AlNSb, AlPAs, AlPSb, InNP, InNAs, InNSb, InPAs, InPSb, GaAINP, GaAINAs, GaAINSb, GaAlPAs, GaAlPSb, GaInNP, GaInNAs, GaInNSb, GalnPAs, GalnPSb, InAINP, InAINAs, InAINSb, InAlPAs, and InAlPSb; the group I-III-VI compound is selected from one or more of CuInS₂, CuInSe₂, and AgInS₂; the perovskite semiconductor material is selected from a doped or undoped inorganic perovskite semiconductor or an organic-inorganic hybrid perovskite semiconductor; the inorganic perovskite semiconductor has a general structure of AMX₃, the organic-inorganic hybrid perovskite semiconductor has a general structure of BMX₃, where A is a Cs⁺; B is an organic amine cation selected from CH₃(CH₂)ₙ₋₂NH³⁺ or [NH₃(CH₂)ₙNH₃]²⁺, n>2; M is a divalent metal cation selected from one or more of Pb²⁺, Sn²⁺, Cu²⁺, Ni²⁺, Cd²⁺, Cr²⁺, Mn²⁺, Co²⁺, Fe²⁺, Ge²⁺, Yb²⁺, and Eu²⁺; and X is a halide anion selected from one or more of Cl⁻, Br⁻, and I⁻; when the quantum dot further includes the shell coated outside the quantum dot material layer, the quantum dot material layer and the shell are different in material.

The present disclosure further provides a light-emitting module including a quantum dot layer, and the quantum dot layer includes the quantum dot as described above.

Optionally, in some embodiments, the light-emitting module includes a first electrode and a second electrode, and the quantum dot layer is disposed between the first electrode and the second electrode.

Optionally, in some embodiments, the light-emitting module further includes:
a hole transport layer disposed between the first electrode and the quantum dot layer;
a hole injection layer disposed between the hole transport layer and the first electrode; and
an electron transport layer disposed between the second electrode and the quantum dot layer;
the first electrode and the second electrode are independently selected from a doped metal oxide particle electrode, a composite electrode, a graphene electrode, a carbon nanotube electrode, a metal element electrode, or an alloy electrode; a material of the doped metal oxide particle electrode is selected from one or more of indium-doped tin oxide, fluorine-doped tin oxide, antimony-doped tin oxide, aluminum-doped zinc oxide, gallium-doped zinc oxide, indium-doped zinc oxide, magnesium-doped zinc oxide, and aluminum-doped magnesium oxide; the composite electrode is selected from AZO/Ag/AZO, AZO/AI/AZO, ITO/Ag/ITO, ITO/AI/ITO, ZnO/Ag/ZnO, ZnO/Al/ZnO, TiO₂/Ag/TiO₂, TiO₂/Al/TiO₂, ZnS/Ag/ZnS, or ZnS/Al/ZnS; a material of the metal electrode is selected from one or more of Ag, Al, Cu, Au, Mo, Pt, Ca, and Ba; and/or
a material of the hole injection layer is selected from one or more of 2,3,6,7,10,11-hexacyano-1,4,5,8,9,12-hexaazatriphenylene, PEDOT, PEDOT: PSS, a derivative of PEDOT: PSS doped with s-MoO₃, 4,4′,4′-tris(N-3-methylphenyl-N-phenylamino)triphenylamine, tetracyanoquinodimethane, copper phthalocyanine, nickel oxide, molybdenum oxide, tungsten oxide, vanadium oxide, molybdenum sulfide, tungsten sulfide, and copper oxide; and/or
a material of the hole transport layer is selected from one or more of 4,4′-N,N′-dicarbazolyl-biphenyl (CBP), N,N′-diphenyl-N,N′-bis(1-naphthyl)-1,1′-biphenyl-4,4″-diamine, N,N′-diphenyl-N,N′-bis(3-methylphenyl)-(1,1′-biphenyl)-4,4′-diamine, N,N′-bis(3-methylphenyl)-N,N′-bis(phenyl)-spiro(spiro-TPD), N,N′-bis(4-(N,N′-diphenyl-amino)phenyl)-N,N′-diphenylbenzidine, 4,4′,4′-tris(N-carbazolyl)-triphenylamine, 4,4′,4′-tris(N-3-methylphenyl-N-phenylamino)triphenylamine, poly [(9,9′-dioctylfluorene-2,7-diyl)-co-(4,4′-(N-(4-sec-butyphenyl)diphenylamine))], poly(4-butylphenyl-diphenylamine) (poly-TPD), polyaniline, polypyrrole, poly(p)phenylenevinylene, poly(phenylenevinylene), poly[2-methoxy-5-(2-ethylhexyloxy)-1,4-phenylenevinylene], poly[2-methoxy-5-(3′,7′-dimethyloctyloxy)-1,4-phenylenevinylene], copper phthalocyanine, aromatic tertiary amines, polynuclear aromatic tertiary amine, 4,4′-bis(N-carbazolyl)-1,1′-biphenyl compound, N,N,N′,N′-tetraarylbiphenylamine, PEDOT:PSS and derivatives thereof, poly(N-vinylcarbazole) (PVK) and derivatives thereof, polymethacrylate and derivatives thereof, poly(9,9-octylfluorene) and derivatives thereof, poly(spirofluorene) and derivatives thereof, N,N′-di(naphthalen-1-yl)-N,N′-diphenylbenzidine, spiro-NPB, doped graphene, non-doped graphene, C60, doped or non-doped NiO, doped or non-doped MoO₂, doped or non-doped WO₂, doped or non-doped V₂O₂, doped or non-doped P-type gallium nitride, doped or non-doped CrO₂, and doped or non-doped CuO;
a material of the electron transport layer is selected from one or more of a metal oxide, a doped metal oxide, a group 2-6 semiconductor material, a group 3-5 semiconductor material, and a group 1-3-6 semiconductor material; the metal oxide is selected from one or more of ZnO, BaO, TiO₂, and SnO₂; a metal oxide of the doped metal oxide is selected from one or more of ZnO, TiO₂, and SnO₂; a doping element of the doped metal oxide is selected from one or more of Al, Mg, Li, In, and Ga; the group 2-6 semiconductor material is selected from one or more of ZnS, ZnSe, and CdS; the group 3-5 semiconductor material is selected from one or more of InP and GaP; the group 1-3-6 semiconductor material is selected from one or more of CuInS and CuGaS.

The present disclosure further provides a method for synthesizing quantum dot, the method including following steps:
dispersing the seed crystal in a first quantum dot precursor;
providing a second quantum dot precursor, mixing and reacting the first quantum dot precursor with the seed crystal dispersed therein and the second quantum dot precursor to have the first quantum dot precursor and the second quantum dot precursor to grow on the surface of the seed crystal to form a quantum dot material layer, and obtaining the quantum dot.

Optionally, in some embodiments, after the step of mixing and reacting the first quantum dot precursor with the seed crystal dispersed therein and the second quantum dot precursor, the method further includes:
injecting a shell precursor, and ripening to form a shell outside the quantum dot material layer.

Optionally, in some embodiments, the seed crystal is a semiconductor seed crystal or a single-crystal seed crystal.

Optionally, in some embodiments, the seed crystal is a ZSM-5 molecular sieve, a Silicalite-1 all-silica molecular sieve, or a nano single-crystal silicon; or
the seed crystal is an intrinsic semiconductor, a P-type doped semiconductor, or an N-type doped semiconductor.

Optionally, in some embodiments, an average particle size of the seed crystal ranges from 1 nm to 2 nm, and an average thickness of the quantum dot material layer ranges from 3 nm to 4 nm; and/or
in the quantum dot, a molar percentage of the seed crystal ranges from 2% to 10%, and a molar percentage of the quantum dot material layer ranges from 90% to 98%.

Optionally, in some embodiments, an average particle size of the seed crystal ranges from 1 nm to 2 nm, an average thickness of the quantum dot material layer ranges from 3 nm to 4 nm, and a total thickness of the shell ranges from 2 nm to 3 nm; and/or
in the quantum dot, a molar percentage of the seed crystal ranges from 2% to 10%, a molar percentage of the quantum dot material layer ranges from 50% to 70%, and a molar percentage of the shell ranges from 20% to 40%.

### BRIEF DESCRIPTION OF DRAWINGS

In order to more clearly illustrate the technical solutions in the present disclosure, the following will briefly introduce the drawings required in the embodiments. Obviously, the drawings in the following description merely represent some of the embodiments of the present disclosure, and other drawings may be obtained by those skilled in the art without creative efforts.

FIG. 1 is a schematic diagram of a structure of a light-emitting module according to an embodiment of the present disclosure.

FIG. 2 is a transmission electron microscope (TEM) image of quantum dots according to Example 1 of the present disclosure.

FIG. 3 is a transmission electron microscope (TEM) image of quantum dots according to Example 2 of the present disclosure.

FIG. 4 is a transmission electron microscope (TEM) image of quantum dots according to Example 3 of the present disclosure.

FIG. 5 is a transmission electron microscope (TEM) image of quantum dots according to Comparative Example of the present disclosure.

FIG. 6 is a flow chart of a method for synthesizing quantum dot according to an embodiment of the present disclosure.

### EMBODIMENTS OF THE PRESENT DISCLOSURE

The technical solutions in the present disclosure will be described clearly and completely below in combination with the drawings in the embodiments of the present disclosure. Obviously, the described embodiments are only part of the embodiments of the present disclosure, rather than all the embodiments. Based on the embodiments in the present disclosure, all the other embodiments obtained by those skilled in the art without creative work are within the protection scope of the present disclosure.

In the present disclosure, unless otherwise explicitly specified and limited, a first feature “on” or “under” a second feature indicates that the first feature and the second feature are directly connected, or that the first feature and the second feature are not directly connected but are connected through another feature therebetween. Moreover, the first feature “on”, “above” or “on top of” the second feature indicates that the first feature is directly above or obliquely above the second feature, or only indicates that the first feature is higher than the second feature in the horizontal height. The first feature “under”, “below” or “underneath” the second feature indicates that the first feature is directly below or obliquely below the second feature, or only indicates that the first feature is lower than the second feature in the horizontal height. In addition, the terms “first” and “second” are only used for descriptive purposes, and may not be understood as indicating or implying relative importance or implicitly indicating the number of the indicated technical features. Therefore, the features defined with “first” and “second” may explicitly or implicitly include one or more features.

The present disclosure provides a quantum dot including a seed crystal and a quantum dot material layer grown on the surface of the seed crystal.

In the quantum dot of the present disclosure, the quantum dot material layer is grown on the surface of the seed crystal, the quantum dot material is attached to the seed crystal for oriented growth, thereby achieving low lattice stress during quantum dot growth, and allowing the quantum dot to have few growth defects and high performance. When the quantum dot is used as a light-emitting material of a quantum dot light-emitting module, the non-radiative recombination phenomenon may be reduced, the exciton quenching may be avoided, thereby the luminous efficiency and the lifetime of the light-emitting module are improved. The quantum dot of the present disclosure may be applied in a quantum dot light-emitting diode (QLED) light-emitting module as a light-emitting layer, and may further be applied in a micro light-emitting diode (Micro-LED) light-emitting module, a mini light-emitting diode (Mini-LED) light-emitting module, a liquid crystal (Liquid Crystal) light-emitting module or other light-emitting modules as a functional layer such as a color conversion layer.

It should be noted that the “seed crystal” is an additive that may form a crystal nucleus in a crystallization method to accelerate or promote the growth of an enantiomer crystal with the same crystal form or spatial configuration. Herein, the “quantum dot material layer” does not refer to a layer formed by a plurality of quantum dots, but refers to a layer formed by a material used to form a quantum dot, for example, a layer formed by CdS, CdSe, CdTe, ZnS or ZnSe.

In some embodiments, the quantum dot is a single-structure quantum dot or a perovskite semiconductor material. The quantum dot only includes a seed crystal and a quantum dot material layer grown on the surface of the seed crystal.

In another embodiment, the quantum dot is a core-shell quantum dot. The quantum dot further includes a shell layer coated outside the quantum dot material layer. That is, the core of the core-shell quantum dot includes the seed crystal and the quantum dot material, and at least one shell layer is coated outside the quantum dot core. The core-shell quantum dot may further be considered as a crystal, which includes a crystal core and a shell layer. The center of the crystal core is the seed crystal, and the crystal core further includes a quantum dot material layer grown on the surface of the seed crystal.

In some embodiments, the seed crystal and the quantum dot material layer may jointly constitute the core of the quantum dot. In another embodiment, the core of the quantum dot may further include other components in addition to the seed crystal and the quantum dot material layer for other purposes, which are not limited herein.

For the core-shell quantum dot, regular seed crystal may be introduced in the initial stage of the growth of the core, so that the quantum dot material may grow directionally in adhesion to the seed crystal in the initial stage of nucleation, thereby reduce the lattice stress in the initial stage of nucleation of the quantum dot, and reduce the growth defects of core of the quantum dot. When the core-shell quantum dot is used as the light-emitting material of the quantum dot light-emitting module, the non-radiative recombination phenomenon may be reduced, the exciton quenching may be avoided, and the luminous efficiency and the lifetime of the light-emitting module may be improved.

For the seed crystal, any material capable of serving as a seed crystal may be used in the present disclosure, such as a ZSM-5 molecular sieve, a Silicalite-1 all-silicon molecular sieve, a nano single-crystal silicon and the like. In some embodiments, the seed crystal is a semiconductor seed crystal. When the semiconductor seed crystal is used, the carrier transport performance of the semiconductor may be improved by doping, so as to modify the quantum dot. In some embodiments, the seed crystal is a single-crystal seed crystal. The single-crystal seed crystal has only one crystal orientation, so that the core of the quantum dot has only one growth crystal orientation, instead of multiple growth crystal orientations which may cause lattice mismatch.

In a more specific embodiment, the seed crystal is a nano single-crystal silicon. The nano single-crystal silicon has semiconductor characteristics and has only one crystal orientation.

In some embodiments, the seed crystal is an intrinsic semiconductor, a P-type doped semiconductor, or an N-type doped semiconductor. By P-doping semiconductor seed crystal, such as P-doping nano single-crystal silicon, to make it a seed crystal with multiple carriers as holes, the hole injection capability of the quantum dot may be improved. By N-doping semiconductor seed crystal, such as nano single-crystal silicon, to make it a seed crystal with multiple carriers as electrons, the electron injection capability of the quantum dot may be improved. Thus, the balance between the electrons and the holes may be further improved, the non-radiative recombination may be reduced, and the luminous efficiency of the quantum dot may be improved.

Optionally, when the quantum dot is the single-structure quantum dot, an average particle size of the seed crystal ranges from 1 nm to 2 nm, and an average thickness of the quantum dot material layer ranges from 3 nm to 4 nm.

Optionally, when the quantum dot is the core-shell quantum dot, an average particle size of the crystal seed crystal ranges from 1 nm to 2 nm, an average thickness of the quantum dot material layer ranges from 3 nm to 4 nm, and a total thickness of the shell ranges from 2 nm to 3 nm.

Optionally, when the quantum dot is the single-structure quantum dot, in the quantum dot, a molar percentage of the seed crystal ranges from 2% to 10%, and a molar percentage of the quantum dot material layer ranges from 90% to 98%. Specifically, the molar percentage of the seed crystal is 4%, and the molar percentage of the quantum dot material layer is 96%.

Optionally, when the quantum dot is the core-shell quantum dot, in the quantum dot, a molar percentage of the seed crystal is ranges from 2% to 10%, a molar percentage of the quantum dot material layer ranges from 50% to 70%, and a molar percentage of the shell ranges from 20% to 40%. Specifically, the molar percentage of the seed crystal is 4%, the molar percentage of the quantum dot material layer is 68%, and the molar percentage of the shell is 28%.

Optionally, a material of the quantum dot material layer and a material of the shell layer (if any) are independently selected from one or more of a group II-VI compound, a group IV-VI compound, a group III-V compound, and a group I-III-VI compound. The group II-VI compound is selected from one or more of CdS, CdSe, CdTe, ZnS, ZnSe, ZnTe, ZnO, HgS, HgSe, HgTe, CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, CdZnSeS, CdZnSeTe, CdZnSTe, CdHgSeS, CdHgSeTe, CdHgSTe, HgZnSeS, HgZnSeTe, and HgZnSTe. The group IV-VI compound is selected from one or more of SnS, SnSe, SnTe, PbS, PbSe, PbTe, SnSeS, SnSeTe, SnSTe, PbSeS, PbSeTe, PbSTe, SnPbS, SnPbSe, SnPbTe, SnPbSSe, SnPbSeTe, SnPbSTe. The group III-V compound is selected from one or more of GaN, GaP, GaAs, GaSb, AlN, AIP, AlAs, AlSb, InN, InP, InAs, InSb, GaNP, GaNAs, GaNSb, GaPAs, GaPSb, AlNP, AlNAs, AlNSb, AlPAs, AlPSb, InNP, InNAs, InNSb, InPAs, InPSb, GaAINP, GaAINAs, GaAINSb, GaAlPAs, GaAlPSb, GaInNP, GaInNAs, GaInNSb, GalnPAs, GalnPSb, InAINP, InAINAs, InAINSb, InAlPAs, and InAlPSb. The group I-III-VI compound is selected from one or more of CuInS₂, CuInSe₂, and AgInS₂. The perovskite semiconductor material is selected from a doped or undoped inorganic perovskite semiconductor or an organic-inorganic hybrid perovskite semiconductor. The inorganic perovskite semiconductor has a general structure of AMX₃, the organic-inorganic hybrid perovskite semiconductor has a general structure of BMX₃, where A is a Cs⁺; B is an organic amine cation selected from CH₃(CH₂)ₙ₋₂NH³⁺ or [NH₃(CH₂)ₙNH₃]²⁺, n>2; M is a divalent metal cation selected from one or more of Pb²⁺, Sn²⁺, Cu²⁺, Ni²⁺, Cd²⁺, Cr²⁺, Mn²⁺, Co²⁺, Fe²⁺, Ge²⁺, Yb²⁺, and Eu²⁺; and X is a halide anion selected from one or more of Cl⁻, Br⁺, and I⁻. In the case where the quantum dot further includes the shell coated outside the quantum dot material layer, the quantum dot material layer and the shell are different in material.

The present disclosure further provides a light-emitting module including a quantum dot layer. The quantum dot layer including the quantum dot above.

The light-emitting module of the present disclosure may be a QLED light-emitting module, a Micro-LED light-emitting module, a Mini-LED light-emitting module, or a liquid crystal light-emitting module. The light-emitting module may be used in the display field or in the photoelectric detection field. According to the type of the light-emitting module, the quantum dot layer may be used as a light-emitting layer or a color conversion layer, or for other purposes. It should be noted that the “quantum dot layer” herein is a layer including or consisting of a plurality of quantum dots.

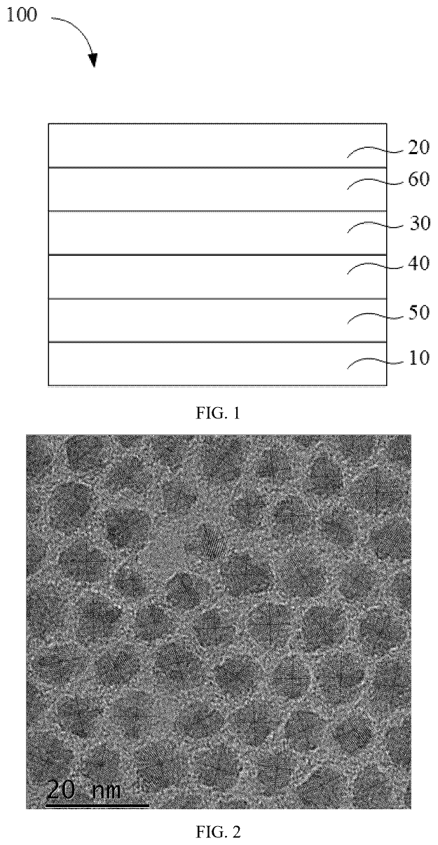

Referring to FIG. 1, the light-emitting module 100 of an embodiment of the present disclosure is a QLED light-emitting module, or a QLED light-emitting device. The light-emitting module 100 includes a first electrode 10, a second electrode 20, and a quantum dot layer 30 disposed between the first electrode 10 and the second electrode 20.

The light-emitting module 100 further includes a hole transport layer 40 disposed between the first electrode 10 and the quantum dot layer 30, a hole injection layer 50 disposed between the hole transport layer 40 and the first electrode 10, and an electron transport layer 60 disposed between the second electrode 20 and the quantum dot layer 30.

Optionally, the first electrode 10 and the second electrode 20 are independently selected from a doped metal oxide particle electrode, a composite electrode, a graphene electrode, a carbon nanotube electrode, a metal element electrode, or an alloy electrode. A material of the doped metal oxide particle electrode is selected from one or more of indium-doped tin oxide, fluorine-doped tin oxide, antimony-doped tin oxide, aluminum-doped zinc oxide, gallium-doped zinc oxide, indium-doped zinc oxide, magnesium-doped zinc oxide, and aluminum-doped magnesium oxide. The composite electrode is selected from AZO/Ag/AZO, AZO/AI/AZO, ITO/Ag/ITO, ITO/AI/ITO, ZnO/Ag/ZnO, ZnO/Al/ZnO, TiO₂/Ag/TiO₂, TiO₂/Al/TiO₂, ZnS/Ag/ZnS, or ZnS/Al/ZnS. A material of the metal electrode is selected from one or more of Ag, Al, Cu, Au, Mo, Pt, Ca, and Ba.

Optionally, a material of the hole transport layer 40 is selected from one or more of 4,4′-N,N′-dicarbazolyl-biphenyl (CBP), N,N′-diphenyl-N,N′-bis(1-naphthyl)-1,1′-biphenyl-4,4″-diamine, N,N′-diphenyl-N,N′-bis(3-methylphenyl)-(1,1′-biphenyl)-4,4′-diamine, N,N′-bis(3-methylphenyl)-N,N′-bis(phenyl)-spiro(spiro-TPD), N,N′-bis(4-(N,N′-diphenyl-amino)phenyl)-N,N′-diphenylbenzidine, 4,4′,4′-tris(N-carbazolyl)-triphenylamine, 4,4′,4′-tris(N-3-methylphenyl-N-phenylamino)triphenylamine, poly [(9,9′-dioctylfluorene-2,7-diyl)-co-(4,4′-(N-(4-sec-butyphenyl)diphenylamine))], poly(4-butylphenyl-diphenylamine) (poly-TPD), polyaniline, polypyrrole, poly(p)phenylenevinylene, poly(phenylenevinylene), poly[2-methoxy-5-(2-ethylhexyloxy)-1,4-phenylenevinylene], poly[2-methoxy-5-(3′,7′-dimethyloctyloxy)-1,4-phenylenevinylene], copper phthalocyanine, aromatic tertiary amines, polynuclear aromatic tertiary amine, 4,4′-bis(N-carbazolyl)-1,1′-biphenyl compound, N,N,N′,N′-tetraarylbiphenylamine, PEDOT:PSS and derivatives thereof, poly(N-vinylcarbazole) (PVK) and derivatives thereof, polymethacrylate and derivatives thereof, poly(9,9-octylfluorene) and derivatives thereof, poly(spirofluorene) and derivatives thereof, N,N′-di(naphthalen-1-yl)-N,N′-diphenylbenzidine, spiro-NPB, doped graphene, non-doped graphene, C60, doped or non-doped NiO, doped or non-doped MoO₂, doped or non-doped WO₂, doped or non-doped V₂O₂, doped or non-doped P-type gallium nitride, doped or non-doped CrO₂, and doped or non-doped CuO.

Optionally, a material of the hole injection layer 50 is selected from one or more of 2,3,6,7,10,11-hexacyano-1,4,5,8,9,12-hexaazatriphenylene, PEDOT, PEDOT: PSS, derivatives of PEDOT: PSS doped with s-MoO₂, 4,4′,4′-tris(N-3-methylphenyl-N-phenylamino)triphenylamine, tetracyanoquinodimethane, copper phthalocyanine, nickel oxide, molybdenum oxide, tungsten oxide, vanadium oxide, molybdenum sulfide, tungsten sulfide, and copper oxide.

Optionally, a material of the electron transport layer 60 is selected from one or more of a metal oxide, a doped metal oxide, a group 2-6 semiconductor material, a group 3-5 semiconductor material, and a group 1-3-6 semiconductor material. The metal oxide is selected from one or more of ZnO, BaO, TiO₂, and SnO₂. A metal oxide of the doped metal oxide is selected from one or more of ZnO, TiO₂, and SnO₂; and a doping element of the doped metal oxide is selected from one or more of Al, Mg, Li, In, and Ga. The group 2-6 semiconductor material is selected from one or more of ZnS, ZnSe, and CdS. The group 3-5 semiconductor material is selected from one or more of InP and GaP. The group 1-3-6 semiconductor material is selected from one or more of CuInS and CuGaS.

The light-emitting module of the present disclosure may avoid exciton quenching and improve luminous efficiency by using the quantum dot. Furthermore, by performing P-type doping or N-type doping on the seed crystal of the quantum dot, the problem of electrons and holes imbalance in the quantum dot light-emitting module may be improved, the non-radiative recombination phenomenon in the quantum dot light-emitting module may be reduced, the luminous efficiency of the quantum dot light-emitting module may be improved, and the problem of short lifetime of the quantum dot light-emitting module may be solved.

Referring to FIG. 6, the present disclosure further provides a method for synthesizing the quantum dot above, the method includes following steps:

101: dispersing the seed crystal in a first quantum dot precursor.

In step 101, the first quantum dot precursor and the second quantum dot precursor respectively include a cation source and an anion source of the quantum dot. The first quantum dot precursor may be an anion precursor or a cation precursor, which is not limited herein. The second quantum dot precursor includes a cation source or an anion source corresponding to the first quantum dot precursor. The seed crystal may be obtained by purchase or obtained by the applicant according to a method disclosed in the literature, for example, the preparation method can refer to Chinese patent application with an application number of 200610028783.X.

Moreover, water and oxygen may cause defects on the surface of the quantum dot, and therefore, in step 101, the first quantum dot precursor may be subjected to water and oxygen removal treatment. A water and oxygen removal method may be stirring and vacuumizing under heating and in an inert gas atmosphere or directly vacuumizing under heating. As described above, for the seed crystal, any material capable of serving as a seed crystal may be used in the present disclosure, for example, ZSM-5 molecular sieve, Silicalite-1 all-silicon molecular sieve, nano single-crystal silicon, etc. In some embodiments, the seed crystal is a semiconductor seed crystal. When the semiconductor seed crystal is used, the carrier transport performance of the semiconductor may be improved by doping, thereby modifying the quantum dot. In some embodiments, the seed crystal is a single crystal seed crystal. The single crystal seed crystal has only one crystal orientation, so that the core of the quantum dot has only one growth crystal orientation, instead of growing in multiple crystal orientations which may cause lattice mismatch.

In a more specific embodiment, the seed crystal is a nanoscale monocrystalline silicon. The nanoscale monocrystalline silicon has semiconductor properties and has only one crystal orientation.

102: providing a second quantum dot precursor, mixing and reacting the first quantum dot precursor with the seed crystal dispersed therein and the second quantum dot precursor to have the first quantum dot precursor and the second quantum dot precursor to grow on the surface of the seed crystal to form a quantum dot material layer, thereby obtaining the quantum dot.

In step 102, the second quantum dot precursor may also be subjected to water and oxygen removal treatment as the first quantum dot precursor.

It should be noted that the number of precursors required for generating quantum dot depends on the type of material of which the quantum dots are composed. The first quantum dot precursor and the second quantum dot precursor may each include one or more anion source or cation source. According to requirements, a plurality of anion sources may be mixed with a plurality of cation sources simultaneously or stepwise, and conversely, a plurality of cation sources may be mixed with a plurality of anion sources simultaneously or stepwise.

A method for mixing and reacting the first quantum dot precursor and the second quantum dot precursor may be a high-temperature thermal injection method. The high-temperature thermal injection method is a classical chemical synthesis method widely used in many fields. One of the characteristics of the method is that external physical cooling is required to lower the thermodynamics of the system below the reaction threshold to quickly terminate the chemical synthesis. The synthesis needs to be terminated by external cooling several seconds after the precursors are injected, thereby obtaining high-quality quantum dot. Specifically, the temperature of the second quantum dot precursor is raised to a temperature required for a nucleation reaction in an inert gas atmosphere, and then the first quantum dot precursor with the seed crystal dispersed therein is quickly injected, so that the first quantum dot precursor and the second quantum dot precursor grow a quantum dot material layer on the input seed crystal, thereby obtaining the quantum dot. Of course, the method of the high-temperature thermal injection method may also be that the first quantum dot precursor with the seed crystals dispersed therein is raised to a temperature required for a nucleation reaction in an inert gas atmosphere, and then the second quantum dot precursor is quickly injected, so that the first quantum dot precursor and the second quantum dot precursor grow a quantum dot material layer on the input seed crystal.

In step 102, the quantum dot material layer is grown, and a quantum dot with a single-structure or a core of a core-shell structure quantum dot may be obtained.

The method for synthesizing the quantum dot introduces a seed crystal in the quantum dot growth stage, so that the quantum dot material has a seed crystal for dependent growth, thereby making the quantum dot have a lower growth driving force, and further improving the crystallization quality of the quantum dot, reducing the number of defects in the initial stage of rapid growth of the quantum dot, and thereby reducing the probability of capture of electrons and holes by the defects. When the quantum dot is used as a light-emitting material, non-radiative recombination in the quantum dot light-emitting process may be reduced, and the luminous efficiency of the quantum dot may be improved. In addition, P-type doping of the seed crystal may increase the hole content in the quantum dot, thereby improving the problem of electrons and holes imbalance in the quantum dot light-emitting module, reducing the non-radiative recombination phenomenon in the quantum dot light-emitting module, improving the luminous efficiency of the quantum dot light-emitting module, and solving the problem of short lifetime of the quantum dot light-emitting module. Conversely, N-type doping also has a similar effect and may be used in a situation where electron injection needs to be increased.

Optionally, in step 102, when the core of a core-shell structure quantum dot is obtained, after step 102, the method for synthesizing the quantum dot further includes the following step:

103: injecting a shell precursor, and ripening to form a shell outside the quantum dot material layer.

In some embodiments, the quantum dot has a core-shell structure, and by introducing P-type doped nano single-crystal silicon in the quantum dot nucleation stage, the quantum dot may firstly have a seed crystal for dependent growth in the nucleation stage, thereby making the quantum dot have a lower nucleation driving force, and further improving the crystallization quality of the quantum dot, reducing the number of defects in the initial stage of rapid nucleation of the quantum dot, thereby reducing the probability of capture of electrons and holes by the defects, reducing non-radiative recombination in the quantum dot light-emitting process, and improving the luminous efficiency of the quantum dot. In addition, P-type doping of the nano single-crystal silicon may increase the hole content in the quantum dot, thereby improving the problem of electrons and holes imbalance in the quantum dot light-emitting module, reducing the non-radiative recombination phenomenon in the quantum dot light-emitting module, improving the luminous efficiency of the quantum dot light-emitting module, and solving the problem of short lifetime of the quantum dot light-emitting module.

Optionally, when the quantum dot is the single-structure quantum dot, an average particle size of the seed crystal ranges from 1 nm to 2 nm, and an average thickness of the quantum dot material layer ranges from 3 nm to 4 nm.

Optionally, when the quantum dot is the core-shell structure quantum dot, an average particle size of the seed crystal ranges from 1 nm to 2 nm, an average thickness of the quantum dot material layer ranges from 3 nm to 4 nm, and a total thickness of the shell ranges from 2 nm to 3 nm.

Optionally, when the quantum dot is the single-structure quantum dot, in the quantum dot, a molar percentage of the seed crystal ranges from 2% to 10%, and a molar percentage of the quantum dot material layer ranges from 90% to 98%. Specifically, the molar percentage of the seed crystal is 4%, and the molar percentage of the quantum dot material layer is 96%.

Optionally, when the quantum dot is the core-shell quantum dot, a molar percentage of the seed crystal ranges from 2% to 10%, a molar percentage of the quantum dot material layer ranges from 50% to 70%, and a molar percentage of the shell layer ranges from 20% to 40%. Specifically, the molar percentage of the seed crystal is 4%, the molar percentage of the quantum dot material layer is 68%, and the molar percentage of the shell is 28%.

Hereinafter, the present disclosure will be specifically described with reference to specific examples, and the following examples are only partial examples of the present disclosure and do not limit the present disclosure.

### EXAMPLE 1

10 mmol of zinc acetate, 10 mL of oleic acid and 20 mL of octadecene were added into a 100 mL three-neck flask, and treated under vacuum at 120° C. for 30 min to remove water and oxygen in the reaction system. Then, the temperature was raised to 320° C. under argon atmosphere, and 2 mmol of P-type doped nano monocrystalline silicon dispersed in trioctylphosphine selenide (Se-TOP) was injected into the reaction system. After reacting at 320° C. for 30 s, 0.3 mmol of cadmium oleate solution was added into the reaction system, and reacted at 320° C. for 20 min to form a core of a quantum dot.

Then, 1 mmol of trioctylphosphine selenide and 0.4 mmol of cadmium oleate were continuously added into the reaction system, and reacted at 320° C. for 30 min. Then, 0.5 mmol of trioctylphosphine selenide was added into the reaction system, and reacted for 10 min. Finally, 0.2 mmol of trioctylphosphine sulfide was added into the reaction system, and reacted for 10 min to complete the ripening of the core.

After the reaction was completed, the reaction solution was washed to obtain a CdZnSe/CdZnSe/ZnSe/ZnS quantum dot with the P-type doped nano monocrystalline silicon as the seed crystal.

After the prepared quantum dots were made into light-emitting devices, the emission peak (EL peak), full width at half maximum (FWHM), current efficiency (CE) and lifetime T95@1knit of the devices were tested. The emission spectrum, half peak width and current efficiency of the light-emitting diode were obtained by testing and calculation with a Keithley 2400 high-precision digital source meter, an Ocean Optic USB2000+ spectrometer and an LS-160 luminance meter. The test method of the lifetime T95@1knit was that the time experienced by the initial brightness LO (nit) of the device to decay to 95% under a constant current, and converted to aging time at 1000 nit. The peak wavelength of the emission spectrum was 474 nm, the half peak width was 15.16 nm, the solution quantum yield of the quantum dots was 52%, the corresponding luminous efficiency was 24.39%, and the lifetime was 277.89 hours.

In the formation process of the core of the quantum dot, zinc acetate and oleic acid reacted to generate zinc oleate, and the zinc oleate acted as a first cation precursor. Octadecene acted as a solvent. Trioctylphosphine selenide acted as a first anion precursor. Cadmium oleate acted as a second cation precursor. The first cation precursor, the first anion precursor, and the second cation precursor reacted to form the CdZnSe quantum dot core.

In the process of forming the shell of the quantum dot, the trioctylphosphine selenide was a first anion precursor for the shell growth, the trioctylphosphine sulfide was a second anion precursor for the shell growth, and the cadmium oleate was a cation precursor for the shell growth. When the Se-TOP and the cadmium oleate were added simultaneously, the cadmium of the quantum dot was distributed in a certain part because the reaction rate of the Se-TOP and the cadmium oleate was faster than that of the Se-TOP and the zinc oleate. The concentrated distribution of the cadmium may lead to the decrease of the conduction band, so that the emission peak of the quantum dots is shifted to the green light or even the red light band. Therefore, the Se-TOP and the cadmium oleate were added step by step quickly.

### EXAMPLE 2

This Example is basically the same as Example 1, except that the nano single-crystal silicon in this Example is undoped.

Finally, a CdZnSe/CdZnSe/ZnSe/ZnS quantum dot with the nano single-crystal silicon as the seed crystal were obtained. The peak wavelength of the emission spectrum was 474 nm, the half peak width was 15.33 nm, the solution quantum yield of the quantum dots was 48%. After the prepared quantum dot was made into a light-emitting device, the luminous efficiency was measured to be 18.38%, and the lifetime was measured to be199.62 hours.

### EXAMPLE 3

This Example is basically the same as Example 1, except that the nano single-crystal silicon in the precursor of the Example is N-type doped nano single-crystal silicon.

Finally, the CdZnSe/CdZnSe/ZnSe/ZnS quantum dot was obtained. The peak wavelength of the emission spectrum was 474 nm, the half peak width was 15.87 nm, the solution quantum yield of the quantum dot was 56%. After the prepared quantum dot was made into a light-emitting device, the luminous efficiency was measured to be 18.11%, and the lifetime was measured to be 201.01 hours.

### COMPARATIVE EXAMPLE

This Comparative Example is basically the same as Example 1, except that the nano single-crystal silicon was not added in the precursor of the Comparative Example.

Finally, the CdZnSe/CdZnSe/ZnSe/ZnS quantum dot was obtained. The peak wavelength of the emission spectrum was 474 nm, the half peak width was 19.59 nm, the solution quantum yield of the quantum dot was 36%. After the prepared quantum dot was made into a light-emitting device, the luminous efficiency was measured to be 13.21%, and the lifetime was measured to be 24.11 hours.

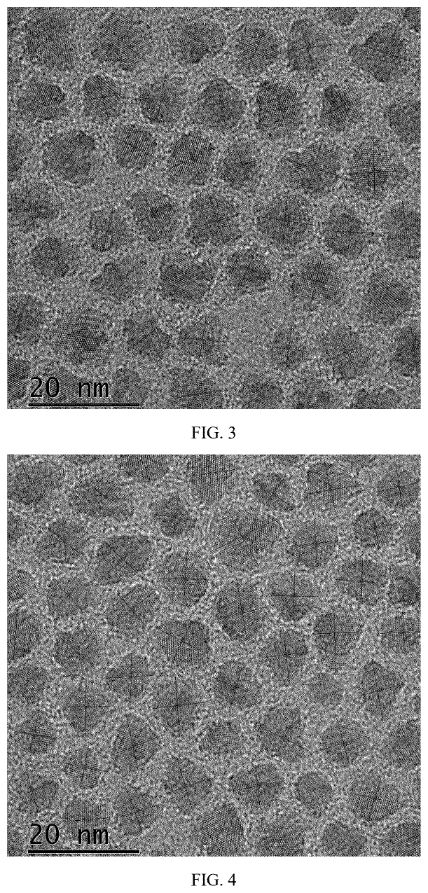

Example 1, Example 2 and Comparative Example were characterized by a transmission electron microscope (TEM), and the characterization results are shown in FIG. 2 to FIG. 4.

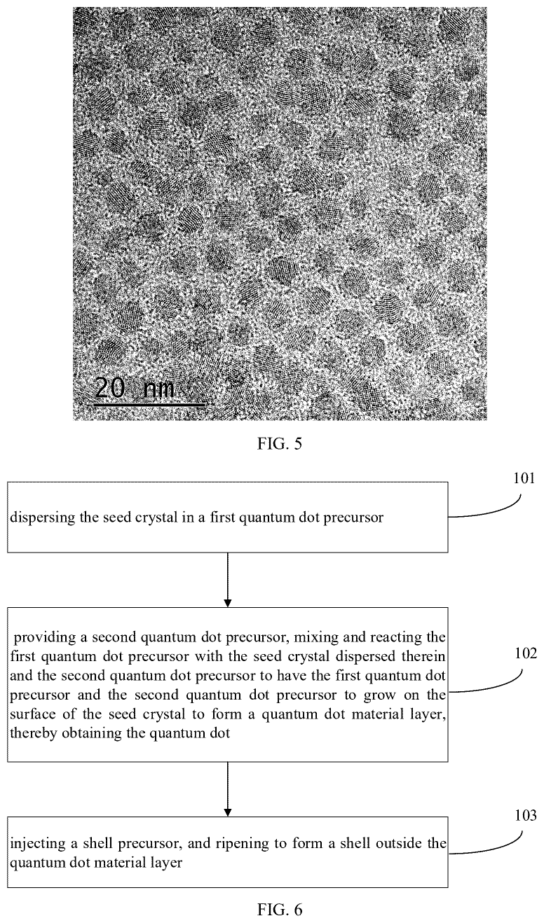

Referring to FIG. 2 to FIG. 5, FIG. 2 to FIG. 4 are TEM photographs of core-shell quantum dots to which seed crystals were added, and FIG. 5 is a TEM photograph of quantum dots to which seed crystal was not added. The darker color in the TEM photograph is the quantum dots. As can be seen from FIG. 2 to FIG. 5, compared to the Comparative Example to which no seed crystal was added, the quantum dot of Example 1 to Example 3 to which seed crystals were added have a larger particle size, and the larger particle size is advantageous for improving the luminous efficiency and the lifetime of the devices prepared by the quantum dot.

Furthermore, the test results of Examples 1-3 and Comparative Example are summarized in the following table.

TABLE 1
the test results of Examples 1-3 and Comparative Example

| | average | peak | | | | |
|---|---|---|---|---|---|---|
| | particle | wave- | half | | | T95@ |
| | size | length | peak | | CE | 1 knit |
| | (nm) | (nm) | width(nm) | yield | (cd/A) | (h) |
| Example 1 | 8.5 | 474 | 15.16 | 52% | 0.2439 | 277.89 |
| Example 2 | 9.4 | 474 | 15.33 | 48% | 0.1838 | 199.62 |
| Example 3 | 8.6 | 474 | 15.87 | 56% | 0.1811 | 201.01 |
| Comparative | 5 | 474 | 19.59 | 36% | 0.1321 | 24.11 |
| Example | | | | | | |

As can be seen from the data in table 1, compared to the Comparative Example to which no seed crystal was added, the peak wavelength of Examples 1-3 to which nano single-crystal silicon were added as seed crystals does not change, but the half peak width is narrowed. Since the smaller the grain diameter is, the larger the corresponding half peak width is, which is consistent with the results of the TEM. Moreover, the luminous efficiency and the lifetime of Examples 1-3 are significantly improved compared to the Comparative Example. Compared to Example 2 to which intrinsic semiconductor nano single-crystal silicon was added, the luminous efficiency and the lifetime of Example 1 in which P-type doping is performed in the seed crystal is further improved, and the reason may be that the P-type doped quantum dot may improve the hole injection capability of the quantum dot, thereby improving the carrier balance.

The technical solutions provided by the embodiments of the present disclosure are described in detail above. The principles and embodiments of the present disclosure have been described with reference to specific embodiments, and the description of the above embodiments is merely intended to aid in the understanding of the method of the present disclosure and its core idea. Meanwhile, for those skilled in the art, the specific implementation manners and application ranges may be changed according to the idea of the present disclosure. In conclusion, the content of the specification should not be understood as a limitation on the present disclosure.

1. A quantum dot, comprising:
a seed crystal; and
a quantum dot material layer grown on the surface of the seed crystal.

2. The quantum dot of claim 1, wherein the quantum dot further comprises a shell coated outside the quantum dot material layer.

3. The quantum dot of claim 1, wherein the seed crystal is a semiconductor seed crystal or a single-crystal seed crystal;
the seed crystal is a ZSM-5 molecular sieve, a Silicalite-1 all-silica molecular sieve, or a nano single-crystal silicon;
the seed crystal is an intrinsic semiconductor, a P-type doped semiconductor, or an N-type doped semiconductor.

4. The quantum dot of claim 1, wherein an average particle size of the seed crystal ranges from 1 nm to 2 nm, and an average thickness of the quantum dot material layer ranges from 3 nm to 4 nm.

5. The quantum dot of claim 4, wherein in the quantum dot, a molar percentage of the seed crystal ranges from 2% to 10%, and a molar percentage of the quantum dot material layer ranges from 90% to 98%.

6. The quantum dot of claim 4, wherein in the quantum dot, a molar percentage of the seed crystal is 4%, and a molar percentage of the quantum dot material layer is 96%.

7. The quantum dot of claim 2, wherein an average particle size of the seed crystal ranges from 1 nm to 2 nm, an average thickness of the quantum dot material layer ranges from 3 nm to 4 nm, and a total thickness of the shell ranges from 2 nm to 3 nm.

8. The quantum dot of claim 7, wherein in the quantum dot, a molar percentage of the seed crystal ranges from 2% to 10%, a molar percentage of the quantum dot material layer ranges from 50% to 70%, and a molar percentage of the shell ranges from 20% to 40%.

9. The quantum dot of claim 7, wherein a molar percentage of the seed crystal is 4%, a molar percentage of the quantum dot material layer is 68%, and a molar percentage of the shell is 28%.

10. The quantum dot of claim 2, wherein a material of the quantum dot material layer and a material of the shell layer are independently selected from one or more of a group II-VI compound, a group IV-VI compound, a group III-V compound, and a group I-III-VI compound; the group II-VI compound is selected from one or more of CdS, CdSe, CdTe, ZnS, ZnSe, ZnTe, ZnO, HgS, HgSe, HgTe, CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, CdZnSeS, CdZnSeTe, CdZnSTe, CdHgSeS, CdHgSeTe, CdHgSTe, HgZnSeS, HgZnSeTe, and HgZnSTe; the group IV-VI compound is selected from one or more of SnS, SnSe, SnTe, PbS, PbSe, PbTe, SnSeS, SnSeTe, SnSTe, PbSeS, PbSeTe, PbSTe, SnPbS, SnPbSe, SnPbTe, SnPbSSe, SnPbSeTe, SnPbSTe; the group III-V compound is selected from one or more of GaN, GaP, GaAs, GaSb, AlN, AIP, AlAs, AlSb, InN, InP, InAs, InSb, GaNP, GaNAs, GaNSb, GaPAs, GaPSb, AlNP, AlNAs, AlNSb, AlPAs, AlPSb, InNP, InNAs, InNSb, InPAs, InPSb, GaAINP, GaAINAs, GaAINSb, GaAlPAs, GaAlPSb, GaInNP, GaInNAs, GaInNSb, GalnPAs, GaInPSb, InAINP, InAINAs, InAINSb, InAlPAs, and InAlPSb; the group I-III-VI compound is selected from one or more of CuInS₂, CuInSe₂, and AgInS₂; the perovskite semiconductor material is selected from a doped or undoped inorganic perovskite semiconductor or an organic-inorganic hybrid perovskite semiconductor; the inorganic perovskite semiconductor has a general structure of AMX₃, the organic-inorganic hybrid perovskite semiconductor has a general structure of BMX₃, where A is a Cs⁺; B is an organic amine cation selected from CH₃(CH₂)ₙ₋₂NH³⁺ or [NH₃(CH₂)ₙNH₃]²⁺, n>2; M is a divalent metal cation selected from one or more of Pb²⁺, Sn²⁺, Cu²⁺, Ni²⁺, Cd²⁺, Cr²⁺, Mn²⁺, Co²⁺, Fe²⁺, Ge²⁺, Yb²⁺, and Eu²⁺; and X is a halide anion selected from one or more of Cl, Br⁻, and I⁻; when the quantum dot further comprises the shell coated outside the quantum dot material layer, the quantum dot material layer and the shell are different in material.

11. A light-emitting module, comprising:
a quantum dot layer, wherein the quantum dot layer comprises a quantum dot comprising a seed crystal and a quantum dot material layer grown on the surface of the seed crystal.

12. The light-emitting module of claim 11, wherein the light-emitting module comprises a first electrode and a second electrode, and the quantum dot layer is disposed between the first electrode and the second electrode.

13. The light-emitting module of claim 12, wherein the light-emitting module further comprises:
a hole transport layer disposed between the first electrode and the quantum dot layer;
a hole injection layer disposed between the hole transport layer and the first electrode; and
an electron transport layer disposed between the second electrode and the quantum dot layer;
the first electrode and the second electrode are independently selected from a doped metal oxide particle electrode, a composite electrode, a graphene electrode, a carbon nanotube electrode, a metal element electrode, or an alloy electrode; a material of the doped metal oxide particle electrode is selected from one or more of indium-doped tin oxide, fluorine-doped tin oxide, antimony-doped tin oxide, aluminum-doped zinc oxide, gallium-doped zinc oxide, indium-doped zinc oxide, magnesium-doped zinc oxide, and aluminum-doped magnesium oxide; the composite electrode is selected from AZO/Ag/AZO, AZO/AI/AZO, ITO/Ag/ITO, ITO/AI/ITO, ZnO/Ag/ZnO, ZnO/Al/ZnO, TiO₂/Ag/TiO₂, TiO₂/Al/TiO₂, ZnS/Ag/ZnS, or ZnS/Al/ZnS; a material of the metal electrode is selected from one or more of Ag, Al, Cu, Au, Mo, Pt, Ca, and Ba;
a material of the hole injection layer is selected from one or more of 2,3,6,7,10,11-hexacyano-1,4,5,8,9,12-hexaazatriphenylene, PEDOT, PEDOT: PSS, a derivative of PEDOT: PSS doped with s-MoO₃, 4,4′,4′-tris(N-3-methylphenyl-N-phenylamino)triphenylamine, tetracyanoquinodimethane, copper phthalocyanine, nickel oxide, molybdenum oxide, tungsten oxide, vanadium oxide, molybdenum sulfide, tungsten sulfide, and copper oxide;
a material of the hole transport layer is selected from one or more of 4,4′-N,N′-dicarbazolyl-biphenyl, N,N′-diphenyl-N,N′-bis(1-naphthyl)-1,1′-biphenyl-4,4″-diamine, N,N′-diphenyl-N,N′-bis(3-methylphenyl)-(1,1′-biphenyl)-4,4′-diamine, N,N′-bis(3-methylphenyl)-N,N′-bis(phenyl)-spiro, N,N′-bis(4-(N,N′-diphenyl-amino)phenyl)-N,N′-diphenylbenzidine, 4,4′,4′-tris(N-carbazolyl)-triphenylamine, 4,4′,4′-tris(N-3-methylphenyl-N-phenylamino)triphenylamine, poly[(9,9′-dioctylfluorene-2,7-diyl)-co-(4,4′-(N-(4-sec-butyphenyl)diphenylamine))], poly(4-butylphenyl-diphenylamine), polyaniline, polypyrrole, poly(p)phenylenevinylene, poly(phenylenevinylene), poly[2-methoxy-5-(2-ethylhexyloxy)-1,4-phenylenevinylene], poly[2-methoxy-5-(3′,7′-dimethyloctyloxy)-1,4-phenylenevinylene], copper phthalocyanine, aromatic tertiary amines, polynuclear aromatic tertiary amine, 4,4′-bis(N-carbazolyl)-1,1′-biphenyl compound, N,N,N′,N′-tetraarylbiphenylamine, PEDOT:PSS and derivatives thereof, poly(N-vinylcarbazole) and derivatives thereof, polymethacrylate and derivatives thereof, poly(9,9-octylfluorene) and derivatives thereof, poly(spirofluorene) and derivatives thereof, N,N′-di(naphthalen-1-yl)-N,N′-diphenylbenzidine, spiro-NPB, doped graphene, non-doped graphene, C60, doped or non-doped NiO, doped or non-doped MoO₂, doped or non-doped WO₂, doped or non-doped V₂O₂, doped or non-doped P-type gallium nitride, doped or non-doped CrO₂, and doped or non-doped CuO;
a material of the electron transport layer is selected from one or more of a metal oxide, a doped metal oxide, a group 2-6 semiconductor material, a group 3-5 semiconductor material, and a group 1-3-6 semiconductor material; the metal oxide is selected from one or more of ZnO, BaO, TiO₂, and SnO₂; a metal oxide of the doped metal oxide is selected from one or more of ZnO, TiO₂, and SnO₂; a doping element of the doped metal oxide is selected from one or more of Al, Mg, Li, In, and Ga; the group 2-6 semiconductor material is selected from one or more of ZnS, ZnSe, and CdS; the group 3-5 semiconductor material is selected from one or more of InP and GaP; the group 1-3-6 semiconductor material is selected from one or more of CuInS and CuGaS.

14. A method for synthesizing quantum dot, comprising following steps:
dispersing the seed crystal in a first quantum dot precursor;
providing a second quantum dot precursor, mixing and reacting the first quantum dot precursor with the seed crystal dispersed therein and the second quantum dot precursor to have the first quantum dot precursor and the second quantum dot precursor to grow on the surface of the seed crystal to form a quantum dot material layer, and obtaining the quantum dot.

15. The method according to claim 14, after the step of mixing and reacting the first quantum dot precursor with the seed crystal dispersed therein and the second quantum dot precursor, the method further comprises:
injecting a shell precursor, and ripening to form a shell outside the quantum dot material layer.

16. The method according to claim 14, wherein the seed crystal is a semiconductor seed crystal or a single-crystal seed crystal;
the seed crystal is a ZSM-5 molecular sieve, a Silicalite-1 all-silica molecular sieve, or a nano single-crystal silicon;
the seed crystal is an intrinsic semiconductor, a P-type doped semiconductor, or an N-type doped semiconductor.

17. The method according to claim 14, wherein an average particle size of the seed crystal ranges from 1 nm to 2 nm, and an average thickness of the quantum dot material layer ranges from 3 nm to 4 nm.

18. The method according to claim 17, wherein in the quantum dot, a molar percentage of the seed crystal ranges from 2% to 10%, and a molar percentage of the quantum dot material layer ranges from 90% to 98%.

19. The method according to claim 11, wherein an average particle size of the seed crystal ranges from 1 nm to 2 nm, an average thickness of the quantum dot material layer ranges from 3 nm to 4 nm, and a total thickness of the shell ranges from 2 nm to 3 nm.

20. The method according to claim 19, wherein in the quantum dot, a molar percentage of the seed crystal ranges from 2% to 10%, a molar percentage of the quantum dot material layer ranges from 50% to 70%, and a molar percentage of the shell ranges from 20% to 40%.
